(19) United States
(12) Patent Application Publication
(10) Pub. No.: US 2019/0221179 A1
(43) Pub. Date: Jul. 18, 2019

(54) DISPLAY PANEL AND DISPLAY APPARATUS USING SAME

(71) Applicants: HKC Corporation Limited, Shenzhen City, Guangdong (CN); Chongqing HKC Optoelectronics Technology Co., Limited, Chongqing (CN)

(72) Inventor: Wei CHEN, Chongqing (CN)

(21) Appl. No.: 15/580,358

(22) PCT Filed: Sep. 19, 2017
(86) PCT No.: PCT/CN2017/102017

§ 371 Date: Dec. 7, 2017

(30) Foreign Application Priority Data
Aug. 25, 2017 (CN) 201710744861.4

(51) Int. Cl. G09G 3/36; G02F 1/1362; G02F 1/1368; H01L 27/12

(52) U.S. Cl. CPC G09G 3/3648; G02F 1/136286; G02F 1/1368; G09G 2300/0809; G02F 2201/52; G02F 2001/136222; G09G 2300/0443; H01L 27/124

(57) ABSTRACT

A display panel includes: a substrate; and a plurality of pixel units arranged in an array, and disposed on the substrate, where each of the pixel units includes a plurality of sub pixels, and each of the sub pixels includes: a primary pixel; at least one secondary pixel, disposed opposite to the primary pixel, and located in a same row as the primary pixel; and a plurality of active switches, separately correspondingly coupled to the primary pixel and the secondary pixel, where each of the pixel units includes a plurality of sub pixels with different colors, and a color of the primary pixel of each sub pixel is the same as a color of the secondary pixel of the sub pixel; and in a same pixel unit, the plurality of sub pixels are disposed in a row direction.

### BACKGROUND

### Technical Field

This application relates to the display field, and in particular, to a display panel and a display apparatus using same.

### Related Art

With the development of flat panel display technologies, liquid-crystal display (LCD) apparatuses have gradually replaced conventional canal ray tube displays due to superior characteristics such as a light and thin design, low power consumption, and no radiation. An LCD apparatus includes a backlight module and a display panel. The display panel is usually formed by a color filter (CF) substrate, a thin film transistor array substrate (TFT array substrate), and a liquid crystal layer (LC layer) disposed between the two substrates. The working principle of the display panel is to control rotation of liquid crystal cells of the LC layer by applying a drive voltage to two glass substrates, so that light rays of the backlight module are refracted to generate an image.

Currently, due to problems such a color cast, in the mainstream of display panels, an upper pixel and a lower pixel are divided, in most cases, into a pixel in a bright region and a pixel in a dark region. The total energy of the two pixels are the same as the original energy. Therefore, the optical performance may be a mixture of two voltage value-transmittance attributes. In addition, by properly adjusting the area ratio between the bright and dark regions, the problem of grayscale whitening can be effectively resolved in a large viewing angle.

Because a design of bright and dark voltage division of pixels are made on the display panel in a vertical direction, the resolution of a displayed image is decreased. Consequently, the watching effect is affected. With respect to the problem, related developers urgently need to provide a new pixel structure.

### SUMMARY

To resolve the foregoing technical problem, an objective of this application is to provide a display panel and a display apparatus using same. According to this application, by changing an arrangement manner of primary pixels and secondary pixels in a pixel unit, the resolution of the display panel can be increased, thereby increasing the contrast ratio and the color saturation rate of the display panel.

The objective of this application is achieved and the technical problem of this application is resolved by using the following technical solutions. A display panel provided according to this application comprises: a substrate; and a plurality of pixel units arranged in an array, and disposed on the substrate, wherein each of the pixel units comprises a plurality of sub pixels, and each of the sub pixels comprises: a primary pixel; at least one secondary pixel, disposed opposite to the primary pixel, and located in a same row as the primary pixel; and a plurality of active switches, separately correspondingly coupled to the primary pixel and the secondary pixel, wherein each of the pixel units comprises a plurality of sub pixels with different colors, and a color of the primary pixel of each sub pixel is the same as a color of the secondary pixel of the sub pixel; and in a same pixel unit, the plurality of sub pixels are disposed in a row direction.

In an embodiment of this application, in a same pixel unit, the primary pixels are disposed in an adjacent manner, and the secondary pixels are disposed in an adjacent manner.

In an embodiment of this application, in a same pixel unit, the primary pixels and the secondary pixels are coupled to a same scanning line, and each of the primary pixels and each of the secondary pixels are separately coupled to a corresponding data line.

In an embodiment of this application, in a same pixel unit, the primary pixels and the secondary pixels are disposed in an adjacent spaced manner, and colors of the primary pixels are different from colors of the adjacent secondary pixels.

In an embodiment of this application, in a same pixel unit, the primary pixels and the secondary pixels are coupled to different scanning lines, and the primary pixel of each sub pixel and the secondary pixel of the sub pixel are coupled to a same data line.

In an embodiment of this application, in a plurality of pixel units, every two adjacent primary pixels with different colors and every two adjacent secondary pixels with different colors are a group, and the pixel units are disposed in an adjacent manner per unit of group.

In an embodiment of this application, in a same group, the two primary pixels are coupled to a same data line and are coupled to different scanning lines, and the two secondary pixels are coupled to a same data line and are coupled to different scanning lines.

In an embodiment of this application, in a same group, the two primary pixels are coupled to different data lines and are coupled to a same scanning line, and the two secondary pixels are coupled to different data lines and are coupled to a same scanning line.

The objective of this application may further be achieved and the technical problem of this application may further be resolved by using the following technical solution.

Another objective of this application is a display apparatus, comprising a control component, and the display panel stated above.

Still another objective of this application is a display panel, comprising: a substrate; a plurality of pixel units arranged in an array, and disposed on the substrate, wherein each of the pixel units comprises a plurality of sub pixels, and each of the sub pixels comprises: a primary pixel and at least one secondary pixel, wherein the primary pixel is disposed opposite to the at least one secondary pixel; and a plurality of active switches, separately coupled to the primary pixel and the secondary pixel, wherein different pixel voltages are respectively charged into the primary pixel and the secondary pixel. Each of the pixel units comprises four sub pixels, comprising a red sub pixel, a green sub pixel, a blue sub pixel, and a white sub pixel. In a same pixel unit, colors of the sub pixels are different, and a color of the primary pixel of each sub pixel is the same as a color of the secondary pixel of the sub pixel. In a same pixel unit, the sub pixels are disposed in a row direction; the primary pixels are disposed in an adjacent manner, and the secondary pixels are disposed in an adjacent manner. In a same pixel unit, the primary pixels and the secondary pixels are coupled to a same scanning line, and each of the primary pixels and each of the secondary pixels are separately coupled to a corresponding data line. In a plurality of pixel units, colors of the primary pixels are different from colors of the adjacent secondary pixels.

According to this application, by changing an arrangement manner of primary pixels and secondary pixels in a pixel unit, the resolution of the display panel can be increased, thereby increasing the contrast ratio and the color saturation rate of the display panel.

### BRIEF DESCRIPTION OF THE DRAWINGS

FIG. 1 is a schematic diagram of an exemplary pixel structure;

FIG. 2 is a schematic diagram of a pixel structure according to an embodiment of this application;

FIG. 3 is a schematic diagram of a pixel structure according to another embodiment of this application;

FIG. 4 is a schematic diagram of a pixel structure according to still another embodiment of this application;

FIG. 5 is a schematic diagram of a pixel structure according to yet another embodiment of this application; and

FIG. 6 is a schematic diagram of a display apparatus according to an embodiment of this application.

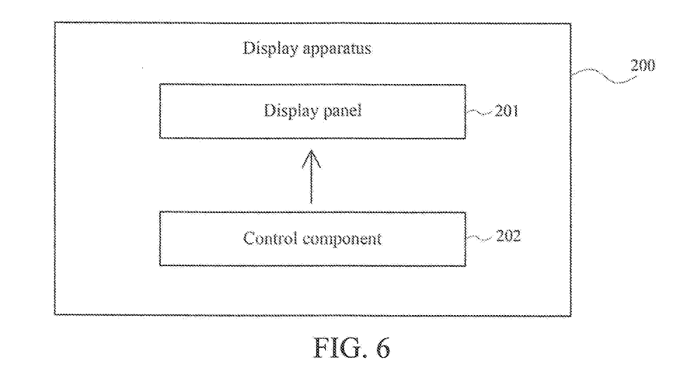

### DETAILED DESCRIPTION

The following embodiments are described with reference to the accompanying drawings, used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, modules with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, a region, and the like are enlarged. In the accompanying drawings, for understanding and ease of description, thicknesses of some layers and regions are enlarged. It should be understood that when a component such as a layer, a film, a region, or a base is described to be “on” another component, the component may be directly on the another component, or there may be an intermediate component.

In addition, throughout this specification, unless otherwise explicitly described to have an opposite meaning, the word “include” is understood as including the component, but not excluding any other component. In addition, throughout this specification, “on” means that one is located above or below a target component and does not necessarily mean that one is located on the top based on a gravity direction.

To further describe the technical means used in this application to achieve the inventive objective and effects thereof, specific implementations, structures, features, and effects of a display panel and a display apparatus using same provided according to this application are described in detail below with reference to the drawings and preferred embodiments.

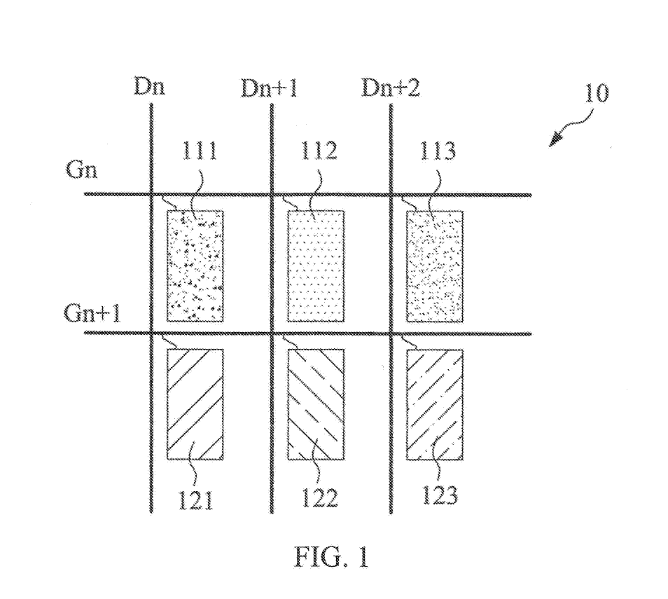

FIG. 1 is a schematic diagram of an exemplary pixel structure. Referring to FIG. 1, an exemplary display panel includes: a plurality of scanning lines (Gn, n is a positive number); and a plurality of data lines (Dn, n is a positive number), disposed perpendicular to and crossing the scanning lines to define a plurality of pixel regions. A plurality of pixel units 10 arranged in an array is disposed in the pixel regions, and is separately coupled to corresponding scanning lines and data lines. The pixel unit includes a plurality of sub pixels. Each of the sub pixels includes a primary pixel and a secondary pixel, separately connected to active switches (not shown in the figure). The primary pixel and the secondary pixel are disposed on different scanning lines in a spaced manner, and are located on a same data line. Different pixel voltages are respectively charged into the primary pixel and the secondary pixel by using the active switches, to reduce the possibility that a panel has a color cast, and the great-visual yellowish phenomenon can be eliminated. However, for such a pixel structure having a low color cast, voltage division and measurement are performed on the pixel unit in a vertical direction. Moreover, for a display panel with a specification such as full high definition (1920*1080) or ultra high definition (3840*2160), the quantity of lines disposed in a vertical direction (such as data lines) differs from the quantity of lines disposed in a horizontal direction (such as scanning lines). Therefore, if voltage division is performed on the pixel unit in the vertical direction, the resolution of an image is reduced, and the overall display effect of a display panel is affected.

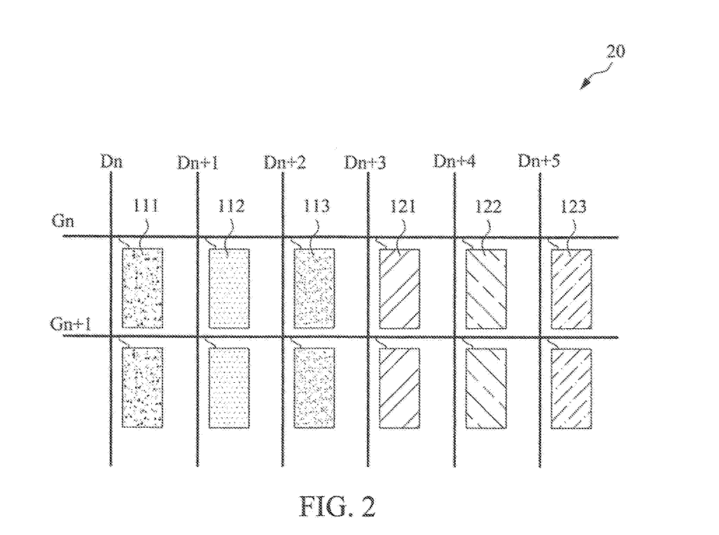

FIG. 2 is a schematic diagram of a pixel structure according to an embodiment of this application. Referring to FIG. 2, in an embodiment of this application, a display panel includes: a substrate (not shown in the figure); and a plurality of pixel units 20 arranged in an array, and disposed on the substrate. Each of the pixel units includes a plurality of sub pixels, for example, three or four sub pixels. In this embodiment, description is made by using an example that the pixel unit includes three sub pixels. However, this application is not limited thereto. Each of the sub pixels includes: a primary pixel (111, 112, 113); and a secondary pixel (121, 122, 123), disposed opposite to the primary pixel, and located in a same row as the primary pixel. A plurality of active switches (not shown in the figure) is separately correspondingly coupled to the primary pixel and the secondary pixel. Each of the pixel units includes three sub pixels with different colors, and the color of the primary pixel of each sub pixel is the same as the color of the secondary pixel of the sub pixel. As shown in FIG. 2, the color of the primary pixel (111, 112, 113) is respectively the same as the color of the sequentially corresponding secondary pixel (121, 122, 123). In a same pixel unit, the three sub pixels are disposed in a row direction.

In an embodiment of this application, in a same pixel unit, the three primary pixels are disposed in an adjacent manner, and the three secondary pixels are disposed in an adjacent manner.

In an embodiment of this application, in a same pixel unit, the primary pixels and the secondary pixels are coupled to a same scanning line (Gn, n is a positive number), and each of the primary pixels and each of the secondary pixels are separately coupled to a corresponding data line (Dn, n is a positive number).

In an embodiment of this application, different pixel voltages are respectively charged into the primary pixel and the secondary pixel. The different pixel voltages are obtained by calculation by using a preset algorithm, so that light with different grayscale values penetrates through the primary pixel and the secondary pixel.

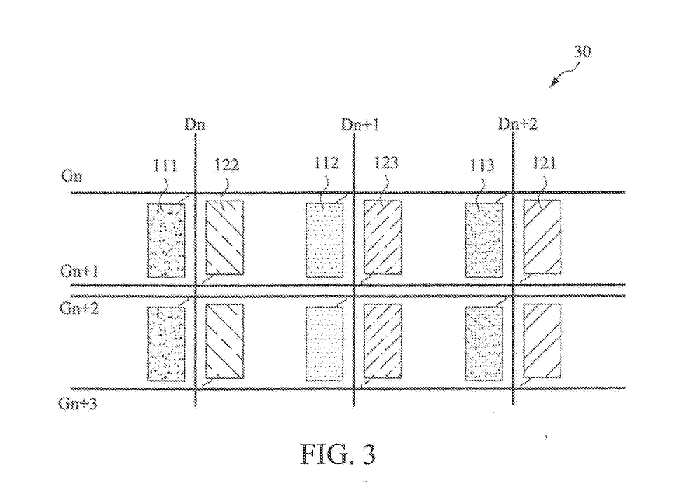

FIG. 3 is a schematic diagram of a pixel structure according to another embodiment of this application. Referring to FIG. 3, a display panel includes: a substrate (not shown in the figure); and a plurality of pixel units 30 arranged in an array, and disposed on the substrate. As compared with the pixel unit 20, in each of the pixel units 30, the primary pixels (111, 112, 113) and the secondary pixels (121, 122, 123) are disposed in an adjacent spaced manner. The colors of the primary pixels are different from the colors of the adjacent secondary pixels. That is, on a same scanning line, each of the primary pixels are adjacent to two secondary pixels with colors different from the color of the primary pixel. Similarly, each of the secondary pixels are adjacent to two primary pixels with colors different from the color of the secondary pixel.

In an embodiment of this application, in a same pixel unit, the primary pixels and the secondary pixels are coupled to different scanning lines, and the primary pixel of each sub pixel and the secondary pixel of the sub pixel are coupled to a same data line.

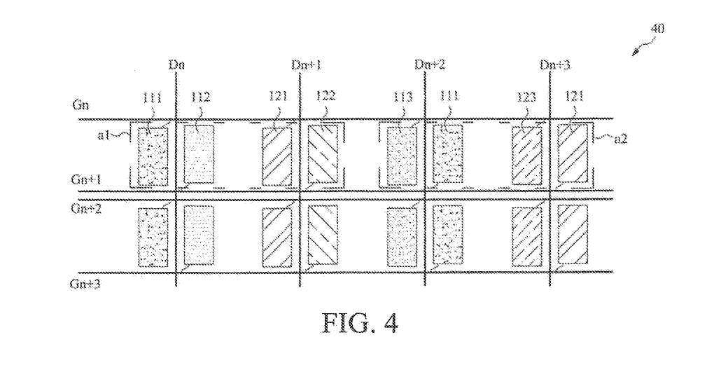

FIG. 4 is a schematic diagram of a pixel structure according to still another embodiment of this application. Referring to FIG. 4, a display panel includes: a substrate (not shown in the figure); and a plurality of pixel units 40 arranged in an array, and disposed on the substrate. As compared with the pixel unit 20, in the plurality of pixel units 40, every two adjacent primary pixels with different colors and every two adjacent secondary pixels with different colors are a group, that is, a pixel group (a1, a2). The pixel units are disposed in an adjacent manner per unit of pixel group (a1, a2). In the same group (a1, a2), the two primary pixels are coupled to a same data line and are coupled to different scanning lines, and the two secondary pixels are coupled to a same data line and are coupled to different scanning lines. By using the pixel group a1 as an example, primary pixels 111 and 112 have different colors, are disposed in an adjacent manner, and are coupled to a same data line Dn and different scanning lines Gn and Gn+1; secondary pixels 121 and 122 have different colors, are disposed in an adjacent manner, and are coupled to a same data line Dn+1 and different scanning lines Gn and Gn+1.

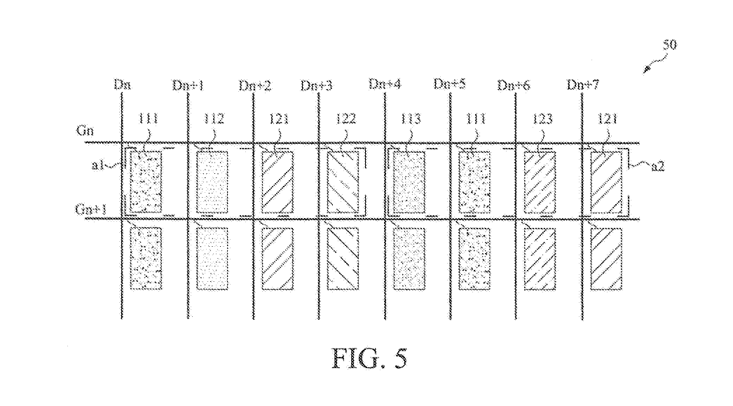

FIG. 5 is a schematic diagram of a pixel structure according to yet another embodiment of this application. Referring to FIG. 5, a display panel includes: a substrate (not shown in the figure); and a plurality of pixel units 50 arranged in an array, and disposed on the substrate. As compared with the pixel unit 40, in a same pixel group (a1, a2) of the pixel unit 50, the two primary pixels are coupled to different data lines, and are coupled to a same scanning line, and the two secondary pixels are coupled to different data lines, and are coupled to a same scanning line. By using the pixel group a1 as an example, primary pixels 111 and 112 have different colors, are disposed in an adjacent manner, and are coupled to different data lines Dn and Dn+1 and a same scanning line Gn; secondary pixels 121 and 122 have different colors, are disposed in an adjacent manner, and are coupled to different data lines Dn+2 and Dn+3 and a same scanning line Gn.

In an embodiment, a display panel includes a plurality of pixel units arranged in an array. As compared with the pixel unit in the foregoing embodiments, each of the pixel units includes a primary pixel and two or more secondary pixels. In this embodiment, description is made by using an example that the pixel unit includes two secondary pixels. The primary pixel and the secondary pixels are located in a same row. The primary pixel and the secondary pixels with a same color may be disposed in a same row in an adjacent manner, or may be disposed in a crossing spaced manner. This depends on the requirement of a designer, and this application is not limited thereto.

In an embodiment of this application, in each pixel unit, a pixel circuit corresponding to the two secondary pixels may enable the two secondary pixels to display with a same brightness, or display with two different brightnesses. For example, the brightness of a first secondary pixel is 70% to 80% of the brightness of the primary pixel, and the brightness of a second secondary pixel is 40% to 50% of the brightness of the primary pixel. The two secondary pixels and the primary pixel may achieve a multi-domain display effect, so that problems such as a color cast may further be resolved, and the display picture quality may be improved.

In an embodiment of this application, for pixels units corresponding to different colors, the quantities of sub pixels included in the pixel units may differ according to a compensated color of a display panel. By using blue and a blue pixel unit as an example, if in a display panel, a blue image has problems such as a color cast and distortion under a large viewing angle relative to an image of another color such as red or green, correspondingly, the blue pixel unit may be formed by one primary pixel and two secondary pixels, and a pixel unit of another color (such as red, green, or white) may be formed by one primary pixel and one secondary pixel.

In some embodiments, the sub pixels, for example, may include red sub pixels (111, 121), green sub pixels (112, 122), and blue sub pixels (113, 123). However, this application is not limited thereto. The sub pixels may further include a sub pixel of a type such as a white sub pixel or a yellow sub pixel. This specification describes the implementation possibility of this application by using examples, instead of limiting this application. Configuration of the colors of the sub pixels depends on a design of a designer.

In some embodiments, the primary pixel or the secondary pixel may be adjacent to a secondary pixel or a primary pixel with a different color, or may be adjacent to a secondary pixel or a primary pixel with a same color. This application is not limited thereto.

In some embodiments, pixel circuits corresponding to the pixel units (20, 30, 40, 50) may be semi-source driving pixel circuits (that is, a configuration manner of sharing one data line between two adjacent pixels) or pixel circuits in a common form (that is, pixels in a same row are coupled to a same scanning line, and are separately correspondingly coupled to a data line). The pixel unit (20, 30, 40, 50) in each embodiment corresponds to one type of pixel unit therein. However, this application is not limited thereto. According to the requirement, each pixel unit may match a pixel circuit in a common form or a semi-source driving pixel circuit, so as to adjust, within a particular range, the quantitative relationship between vertically disposed lines and horizontally disposed lines in a display panel, thereby achieving a better display effect.

Referring to FIG. 2 to FIG. 5, in an embodiment of this application, a display apparatus 200 includes a control component 202, and further includes a display panel 201 having the technical features of the foregoing embodiments, and the pixel units (20, 30, 40, 50) included in the display panel 201.

In an embodiment, the display panel 201 may be, for example, an LCD panel, such as a vertical alignment (VA) type display panel. The VA type display panel may include a TFT substrate, a CF substrate, and an LC layer formed between the two substrates. In an embodiment, an active array (TFT) and a CF of this application may be formed on a same substrate.

In some embodiments, the display panel 201 of this application may be a curved-surface display panel 201.

In some embodiments, the display panel 201 of this application may further be, for example, a twisted nematic (TN) display panel, a super twisted nematic (STN) display panel, an optically compensated birefringence (OCB) display panel, an organic light emitting diode (OLED) display panel, a QLED display panel, a curved-surface display panel, or a plasma display panel.

According to this application, by changing an arrangement manner of primary pixels and secondary pixels in the pixel units (20, 30, 40, 50), and making a voltage division design in directions of horizontal scanning lines, the resolution of the display panel can be increased, thereby increasing the contrast ratio and the color saturation rate of the display panel, and improving the image display effect.

The wordings such as “in some embodiments” and “in various embodiments” are repeatedly used. They usually do not refer to a same embodiment; but they may refer to a same embodiment. The words, such as “comprise”, “have”, and “include”, are synonyms, unless other meanings are indicated in the context thereof.

The foregoing descriptions are merely embodiments of this application, and are not intended to limit this application in any form. Although this application has been disclosed above through the specific embodiments, the embodiments are not intended to limit this application. Any person skilled in the art can make some variations or modifications, namely, equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A display panel, comprising:
a substrate; and
a plurality of pixel units arranged in an array, and disposed on the substrate, wherein each of the pixel units comprises a plurality of sub pixels, and each of the sub pixels comprises:
a primary pixel;
at least one secondary pixel, disposed opposite to the primary pixel, and located in a same row as the primary pixel; and
a plurality of active switches, separately correspondingly coupled to the primary pixel and the secondary pixel, wherein
each of the pixel units comprises a plurality of sub pixels with different colors, and a color of the primary pixel of each sub pixel is the same as a color of the secondary pixel of the sub pixel; and
in a same pixel unit, the plurality of sub pixels are disposed in a row direction.

2. The display panel according to claim 1, wherein in a same pixel unit, the primary pixels are disposed in an adjacent manner, and the secondary pixels are disposed in an adjacent manner.

3. The display panel according to claim 2, wherein in a same pixel unit, the primary pixels and the secondary pixels are coupled to a same scanning line, and each of the primary pixels and each of the secondary pixels are separately coupled to a corresponding data line.

4. The display panel according to claim 1, wherein in a same pixel unit, the primary pixels and the secondary pixels are disposed in an adjacent spaced manner.

5. The display panel according to claim 4, wherein colors of the primary pixels are different from colors of the adjacent secondary pixels.

6. The display panel according to claim 5, wherein in a same pixel unit, the primary pixels and the secondary pixels are coupled to different scanning lines, and the primary pixel of each sub pixel and the secondary pixel of the sub pixel are coupled to a same data line.

7. The display panel according to claim 1, wherein in a plurality of pixel units, every two adjacent primary pixels with different colors and every two adjacent secondary pixels with different colors are a group.

8. The display panel according to claim 7, wherein the pixel units are disposed in an adjacent manner per unit of group.

9. The display panel according to claim 8, wherein in a same group, the two primary pixels are coupled to a same data line and are coupled to different scanning lines, and the two secondary pixels are coupled to a same data line and are coupled to different scanning lines.

10. The display panel according to claim 8, wherein in a same group, the two primary pixels are coupled to different data lines and are coupled to a same scanning line, and the two secondary pixels are coupled to different data lines and are coupled to a same scanning line.

11. A display apparatus, comprising:
a control component; and
a display panel, comprising:
a substrate;
a plurality of pixel units arranged in an array, and disposed on the substrate, wherein each of the pixel units comprises a plurality of sub pixels, and each of the sub pixels comprises:
a primary pixel;
at least one secondary pixel, disposed opposite to the primary pixel, and located in a same row as the primary pixel; and
a plurality of active switches, separately correspondingly coupled to the primary pixel and the secondary pixel, wherein
each of the pixel units comprises a plurality of sub pixels with different colors, and a color of the primary pixel of each sub pixel is the same as a color of the secondary pixel of the sub pixel; and
in a same pixel unit, the plurality of sub pixels are disposed in a row direction.

12. The display apparatus according to claim 11, wherein in a same pixel unit, the primary pixels are disposed in an adjacent manner, and the secondary pixels are disposed in an adjacent manner.

13. The display apparatus according to claim 12, wherein in a same pixel unit, the primary pixels and the secondary pixels are coupled to a same scanning line, and each of the primary pixels and each of the secondary pixels are separately coupled to a corresponding data line.

14. The display apparatus according to claim 11, wherein in a same pixel unit, the primary pixels and the secondary pixels are disposed in an adjacent spaced manner.

15. The display apparatus according to claim 14, wherein colors of the primary pixels are different from colors of the adjacent secondary pixels.

16. The display apparatus according to claim 15, wherein in a same pixel unit, the primary pixels and the secondary pixels are coupled to different scanning lines, and the primary pixel of each sub pixel and the secondary pixel of the sub pixel are coupled to a same data line.

17. The display apparatus according to claim 11, wherein in a plurality of pixel units, every two adjacent primary pixels with different colors and every two adjacent secondary pixels with different colors are a group, and the pixel units are disposed in an adjacent manner per unit of group.

18. The display apparatus according to claim 17, wherein in a same group, the two primary pixels are coupled to a same data line and are coupled to different scanning lines, and the two secondary pixels are coupled to a same data line and are coupled to different scanning lines.

19. The display apparatus according to claim 17, wherein in a same group, the two primary pixels are coupled to different data lines and are coupled to a same scanning line, and the two secondary pixels are coupled to different data lines and are coupled to a same scanning line.

20. A display panel, comprising:
a substrate;
a plurality of pixel units arranged in an array, and disposed on the substrate, wherein each of the pixel units comprises a plurality of sub pixels, and each of the sub pixels comprises:
a primary pixel and at least one secondary pixel, wherein the primary pixel is disposed opposite to the at least one secondary pixel; and
a plurality of active switches, separately coupled to the primary pixel and the secondary pixel, wherein different pixel voltages are respectively charged into the primary pixel and the secondary pixel, wherein
each of the pixel units comprises four sub pixels, comprising a red sub pixel, a green sub pixel, a blue sub pixel, and a white sub pixel;
in a same pixel unit, colors of the sub pixels are different, and a color of the primary pixel of each sub pixel is the same as a color of the secondary pixel of the sub pixel;
in a same pixel unit, the sub pixels are disposed in a row direction;
in a same pixel unit, the primary pixels are disposed in an adjacent manner, and the secondary pixels are disposed in an adjacent manner;
in a same pixel unit, the primary pixels and the secondary pixels are coupled to a same scanning line, and each of the primary pixels and each of the secondary pixels are separately coupled to a corresponding data line; and
in a plurality of pixel units, colors of the primary pixels are different from colors of the adjacent secondary pixels.
